(19) United States
(12) Patent Application Publication
(10) Pub. No.: US 2026/0059733 A1
(43) Pub. Date: Feb. 26, 2026

(54) METHOD OF FORMING MEMORY DEVICE

(71) Applicant: NANYA TECHNOLOGY CORPORATION, New Taipei City (TW)

(72) Inventor: Wei Yu CHEN, New Taipei City (TW)

(21) Appl. No.: 18/813,046

(22) Filed: Aug. 23, 2024

(51) Int. Cl. H10B 12/00

(52) U.S. Cl. CPC H10B 12/053

(57) ABSTRACT

The embodiments of the present disclosure provide a method of forming a memory device including the following steps. A photoresist is formed on a dielectric structure. A trench is formed through the photoresist into the dielectric structure to expose a gate electrode embedded in the dielectric structure. The photoresist is removed by an ashing gas, where the ashing gas has an oxidizing capacity to oxidize a surface of a Si wafer into an oxide layer with a thickness thinner than 8 Å. A first nitride spacer is formed lining the trench and covering the gate electrode. A metal layer is formed filling the trench.

### BACKGROUND

### Field of Invention

The present disclosure relates to a method of forming a memory device.

### Description of Related Art

Memory cells in the device, such as dynamic random access memory (DRAM), have been scaled down continuously to integrate a larger number of the memory cells in a given area. This scaling down process can lead to certain problems in the formation of memory cells. For example, TiN presents lower line resistance than W/TiN stack as critical dimensions shrink, which makes TiN suitable for the word line in memory cells. However, TiN gets oxidation easily, which may cause the high contact resistance between the word line and the metal contact.

### SUMMARY

An aspect of the disclosure is to provide a method of forming a memory device that may efficiently solve the aforementioned problems.

According to one embodiment of this disclosure, a method of forming a memory device includes forming a photoresist on a dielectric structure, forming a trench through the photoresist into the dielectric structure to expose a gate electrode embedded in the dielectric structure, removing the photoresist by an ashing gas having an oxidizing capacity to oxidize a surface of a Si wafer into an oxide layer with a thickness thinner than 8 Å, forming a first nitride spacer lining the trench and covering the gate electrode, and forming a metal layer filling the trench.

According to one embodiment of this disclosure, a method of forming a memory device includes providing a gate structure embedded in a dielectric structure, where the gate structure includes a gate electrode and a gate dielectric surrounding the gate electrode. The method also includes forming a photoresist on the dielectric structure and etching a trench through the photoresist into the dielectric structure to expose a top surface of the gate electrode, where at least a portion of the top surface of the gate electrode is oxidized into an oxide portion. The method also includes removing the photoresist by an ashing gas, where the oxide portion of the gate electrode is reduced by the ashing gas. The method also includes forming a contact in the trench and in contact with the gate structure.

Accordingly, in the method of forming the memory device of some embodiments of the present disclosure, the photoresist for forming the trench on the gate structure is removed by the ashing gas that may not oxidize the gate electrode and even reduce the oxide portion of the gate electrode. Therefore, the contact resistance between the gate structure and the contact may be reduced, which improves the performance of the memory device.

It is to be understood that both the foregoing general description and the following detailed description are by examples, and are intended to provide further explanation of the invention as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a flow chart of a forming method of a memory device according to some embodiments of the present disclosure.

FIGS. 2-5 illustrate cross-sectional views of intermediate stages of forming the memory device according to some embodiments of the present disclosure.

FIGS. 6A-6C illustrate cross-sectional views of intermediate stages of forming the memory device according to one embodiment of the present disclosure.

FIGS. 7A-7E illustrate cross-sectional views of intermediate stages of forming the memory device according to another embodiment of the present disclosure.

### DETAILED DESCRIPTION

The following disclosure provides many different embodiments, or examples, for implementing different features of the provided subject matter. Specific examples of components, arrangements, etc., are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides a method of forming a memory device, which includes removing the photoresist for forming the trench on the gate structure by an ashing gas. Since the ashing gas has an oxidizing capacity to oxidize a surface of a Si wafer into an oxide layer with a thickness thinner than 8 Å, the ashing gas may not oxidize the gate electrode of the gate structure and even reduce the oxide portion of the gate electrode. Therefore, the contact resistance between the gate structure and the contact may be reduced, which improves the performance of the memory device.

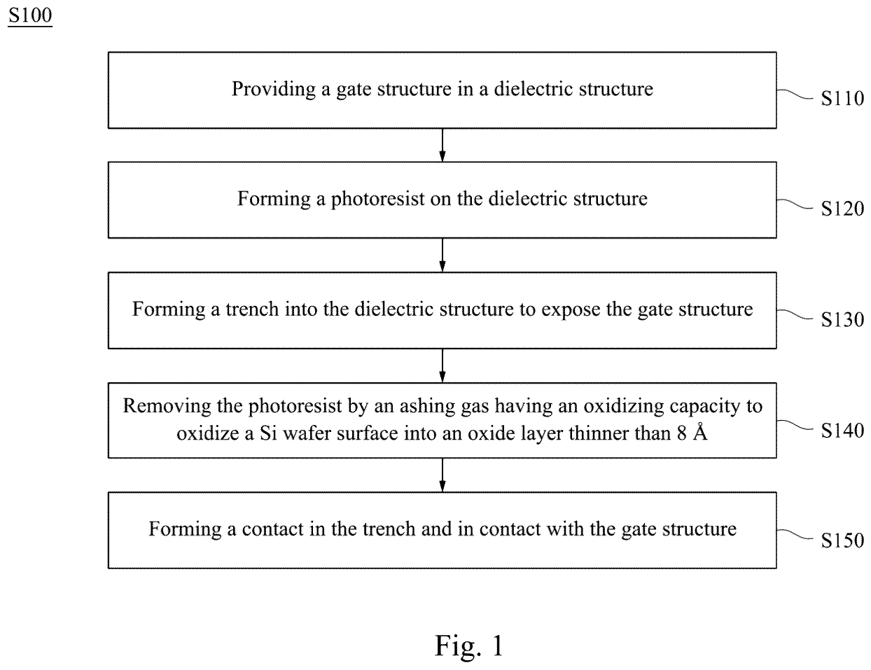

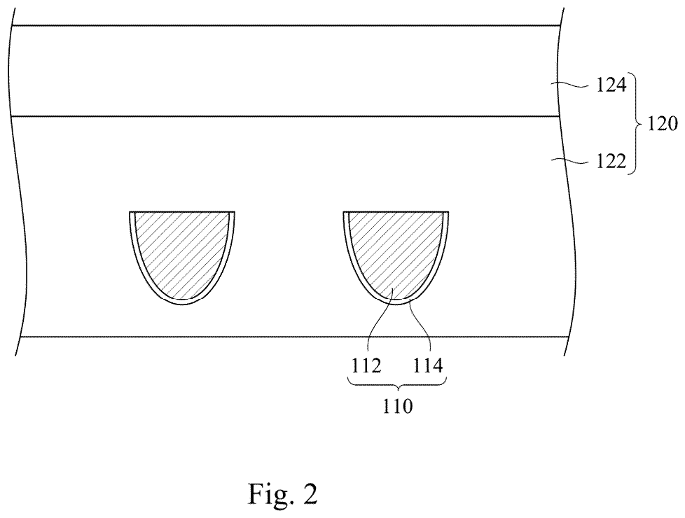

According to some embodiments of the present disclosure, FIG. 1 illustrates a flow chart of a forming method S100 of a memory device. As shown in FIG. 1, the method S100 includes the operation S110 to the operation S150. The details of the method S100 will be further described along with FIGS. 2-7E illustrating cross-sectional views of intermediate stages of forming the memory device.

It should be noted that, unless otherwise stated, when FIGS. 2-7E show or illustrate a series of steps of the embodiments, the description sequence of these steps should not be limited. For example, some steps may be taken in a different order than the described embodiments, some steps may occur simultaneously, some steps may not be required, and/or some steps may be repeated. In addition, additional steps may be performed before, during, or after the illustrated steps to complete forming the memory device.

Referring to FIG. 1 and FIG. 2, in the operation S110 of the method S100, a gate structure 110 in a dielectric structure 120 is provided. The dielectric structure 120 may act as a substrate layer of the memory device, while the gate structure 110 is disposed in the active area of the memory device. Specifically, the gate structure 110 includes a gate electrode 112 and a gate dielectric 114 surrounding the gate electrode 112. The gate electrode 112 and the gate dielectric 114 are covered and surrounded by the dielectric material of the dielectric structure 120 so that the gate structure 110 is embedded in the dielectric structure 120. In some embodiments, the gate structure 110 may serve as a buried word line of the memory device.

In some embodiments, as the critical dimension of the gate structure 110 shrinks to nanoscale, the gate electrode 112 may be made of a metal nitride material to reduce the line resistance. For example, a full titanium nitride (TiN) material shows lower line resistance than a tungsten/titanium nitride (W/TIN) stack when the critical dimension is beneath 18 nm, which makes TIN more suitable for a buried gate electrode 112. In some preferred embodiments, the gate electrode 112 may be substantially composed of TiN when the critical dimension of the gate structure 110 is smaller than or equal to 18 nm.

In some embodiments, the dielectric structure 120 may be made of multiple dielectric materials. As shown in FIG. 2, the dielectric structure 120 may include a first dielectric layer 122 and a second dielectric layer 124 disposed on the first dielectric layer 122, where the first dielectric layer 122 and the second dielectric layer 124 include different materials. For example, the first dielectric layer 122 may be made of oxide, such as silicon oxide, while the second dielectric layer 124 may be made of nitride such as silicon nitride.

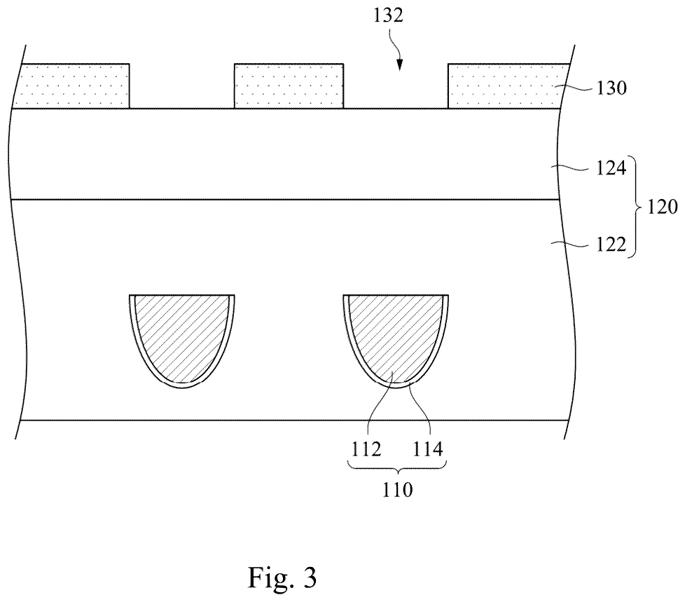

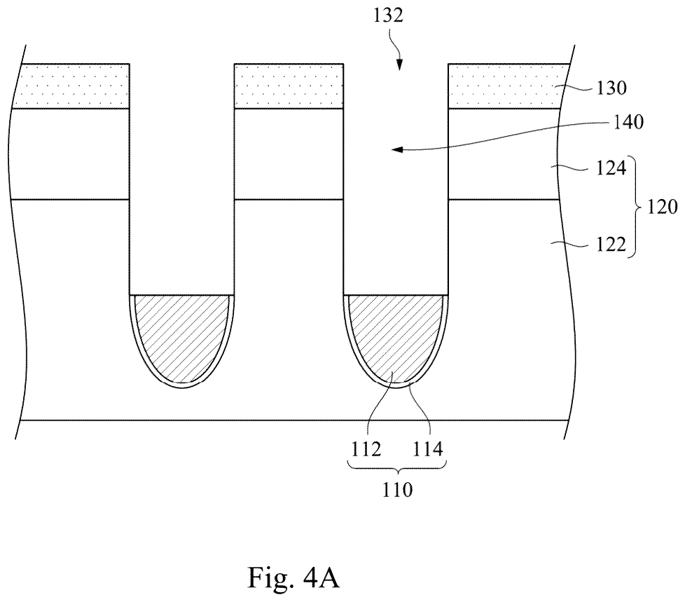

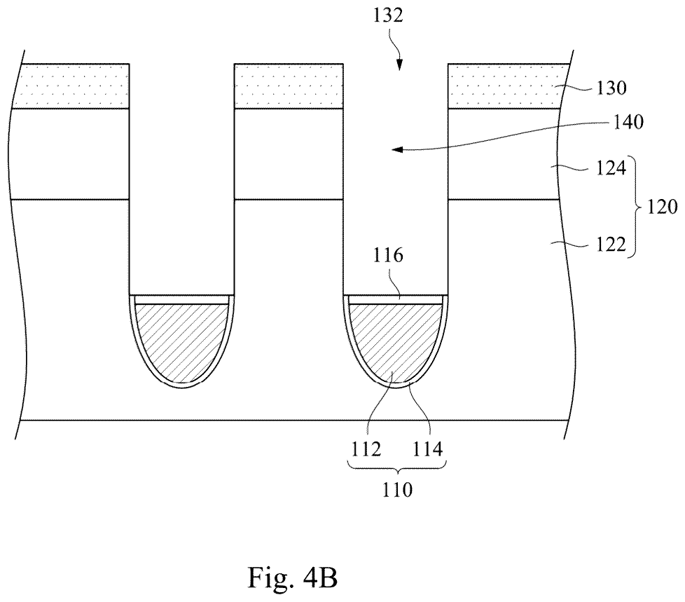

Referring to FIG. 1 and FIG. 3, in the operation S120 of the method S100, a photoresist 130 with an opening 132 is formed on the dielectric structure 120. Specifically, the photoresist 130 may first be formed over the top surface of the dielectric structure 120 by using a spin-on technique. Then, the photoresist 130 may be patterned to form the opening 132 exposing the top surface of the dielectric structure 120 by using acceptable photolithography techniques. The position of the opening 132 corresponds to later formed trench, such as the trench 140 in FIG. 4A, exposing the gate structure 110. In other words, the projection of the opening 132 along Z-axis direction is at least partially overlapped with the gate structure 110.

Referring to FIG. 1 and FIG. 4A, in the operation S130 of the method S100, a trench 140 is formed into the dielectric structure 120 to expose the gate structure 110. Specifically, an etching process, such as dry etching, may be performed through the opening 132 of the photoresist 130 into the dielectric structure 120 to form the trench 140. The etching process may be stopped at a top surface of gate structure 110 so that the gate structure 110 basically remains non-etched. After the etching process, the trench 140 exposes at least the gate electrode 112 of the gate structure 110. In some embodiments which the gate electrode 112 is the main part of the top surface of the gate structure 110, as shown in FIG. 4A, the top surface of the gate electrode 112 may be fully exposed by the trench 140. The gate dielectric 114 around the gate electrode 112 may also be exposed by the trench 140.

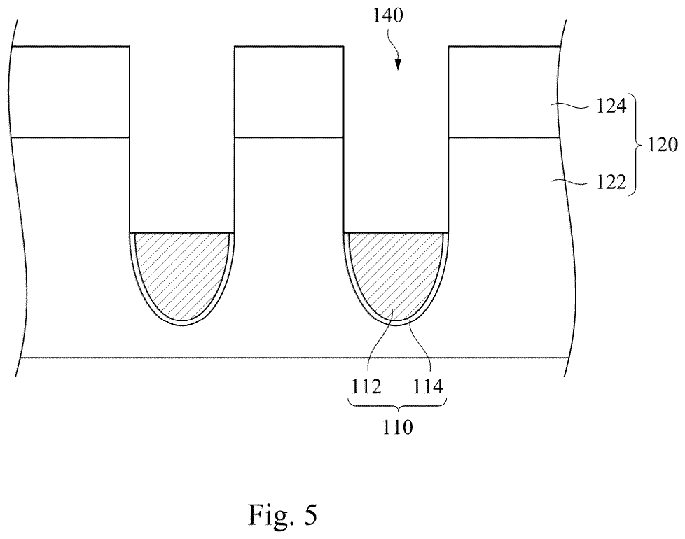

Referring to FIG. 1 and FIG. 5, in the operation S140 of the method S100, the photoresist 130 is removed by an ashing gas 150. Since the gate electrode 112 is exposed by the trench 140 while removing the photoresist 130, the ashing gas 150 may also reach the gate electrode 112. As mentioned above, the gate electrode 112 may be made of low line resistance material, such as TiN or other metal nitride material, to reduce the resistance of the gate structure 110. However, the gate electrode 112 made of the metal nitride material can be easily oxidized when being exposed to the external environment. If the gate electrode 112 is undesirably oxidized, the contact resistance between the gate electrode 112 and the later formed elements, such as contacts, may be increased. Therefore, the component of the ashing gas 150 is carefully considered.

In some embodiments, the component of the ashing gas 150 may be different from that of the etching gas for etching the trench 140 to prevent the gate electrode 112 from oxidation. For example, the ashing gas 150 may have a weak oxidizing capacity to prevent the gate electrode 112 from oxidation. Specifically, the ashing gas 150 may have an oxidizing capacity to oxidize a surface of a Si wafer into an oxide layer with a thickness thinner than 8 Å. If the ashing gas 150 can oxidize the surface of the Si wafer into an oxide layer with a thickness equal to or thicker than 8 Å, the ashing gas 150 may significantly oxidize the metal nitride material of the gate electrode 112. In other words, when the ashing gas 150 cannot oxide the Si wafer surface into an oxide layer equal to or thicker than 8 Å, the oxidizing capacity of the ashing gas 150 is lower than the oxidizing capacity to oxidize the gate electrode 112.

In some embodiments, the ashing gas 150 may have a reducing capacity to reduce the oxide ratio in the gate electrode 112, which ensures the top surface of the gate electrode 112 is free of oxides. As shown in FIG. 4B, once the gate electrode 112 is exposed by the trench 140, the gate electrode 112 may be undesirably oxidized. For example, a portion of the top surface of the gate electrode 112 may be oxidized into an oxide portion 116 before ashing the photoresist 130. Since the ashing gas 150 has the reducing capacity, the ashing gas 150 reaching the gate electrode 112 may reduce the oxide portion 116 of the gate electrode 112 during the ashing process. Therefore, the top surface of the gate electrode 112 is free of the oxide portion 116 after removing the photoresist 130, as shown in FIG. 5.

In some embodiments which the ashing gas includes oxygen, an oxygen ratio of the ashing gas 150 may be lower than or equal to 60% to reduce the oxidizing capacity and increase the reducing capacity of the ashing gas 150. If the oxygen ratio of the ashing gas 150 is higher than 60%, the metal nitride material of the gate electrode 112 may be easily oxidized. For example, the ashing gas 150 may include a first ratio of NH₃ and a second ratio of O₂. The total of the first ratio and the second ratio equals 100%, while the second ratio is lower than or equal to 60%. In some embodiments, the ashing gas 150 may include 40% to 50% of NH₃ and 50% to 60% of O₂, for example, 40% of NH₃ and 60% of O₂, 45% of NH₃ and 55% of O₂, or 50% of NH₃ and 50% of O₂.

In some other embodiments, the ashing gas 150 may be free of oxygen to reduce the oxidizing capacity and increase the reducing capacity of the ashing gas 150. For example, the ashing gas 150 may include a first ratio of H₂ and a second ratio of N₂, while the total of the first ratio and the second ratio equals 100%. The second ratio may be higher than or equal to the first ratio such that the ashing rate of the photoresist can be easily controlled, and the oxidation risk of the gate materials can be reduced. In some embodiments, the ashing gas 150 may include 4% to 50% of H₂ and 50% to 96% of N₂, for example, 50% of H₂ and 50% of N₂, 40% of H₂ and 60% of N₂, 30% of H₂ and 70% of N₂, 20% of H₂ and 80% of N₂, 10% of H₂ and 90% of N₂, or 5% of H₂ and 95% of N₂.

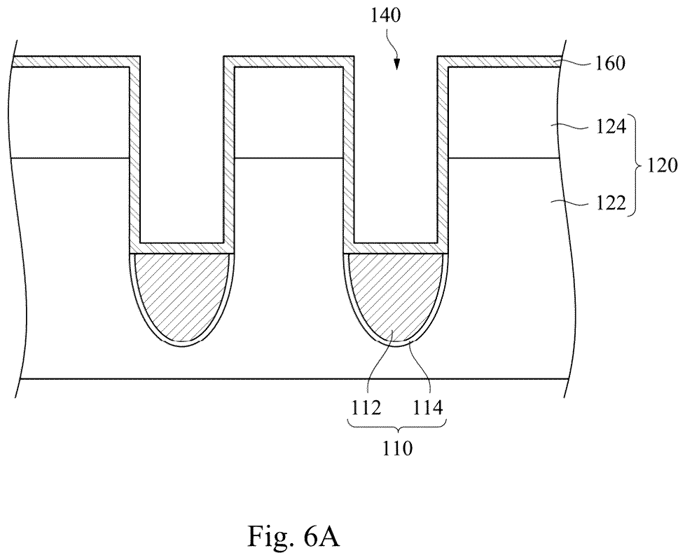

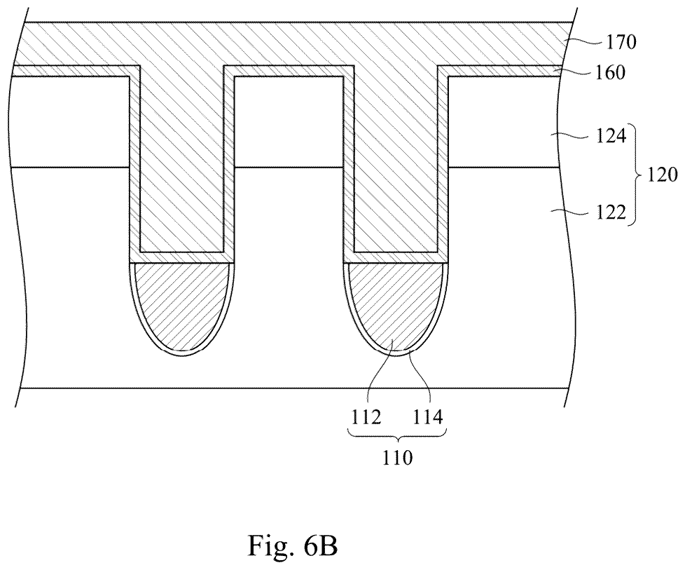

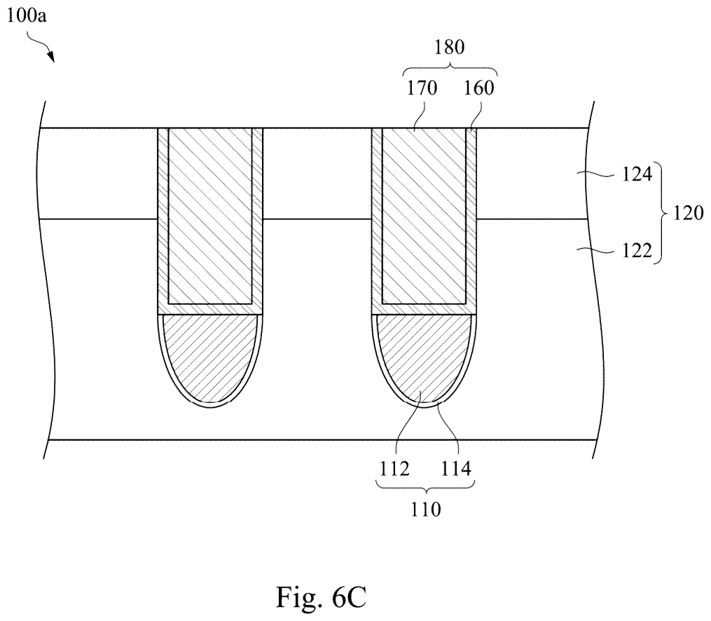

FIGS. 6A-6C illustrate cross-sectional views of one embodiment of the operation S150 of the method S100 in FIG. 1, where a contact 180 is formed in the trench 140 to contact the gate structure 110. Referring to FIG. 6A, a first nitride spacer 160 is formed to line the trench 140 and cover the gate electrode 112. Specifically, the first nitride spacer 160 may be conformally formed on the sidewalls of the trench 140, the bottom surface of the trench 140, and the top surface of the dielectric structure 120 by, for example, chemical vapor deposition (CVD) or atomic layer deposition (ALD). After forming the first nitride spacer 160, a portion of the trench 140 is remained above the first nitride spacer 160, and the first nitride spacer 160 directly contacts the top surface of the gate electrode 112.

Referring to FIG. 6B, a metal layer 170 is formed to fill the trench 140. Specifically, the metal layer 170 is formed in the trench 140 and above the dielectric structure 120 by using deposition process, plating process, or other suitable techniques. The metal layer 170 directly contacts the first nitride spacer 160 while being separated from the gate structure 110 and the dielectric structure 120. As the first nitride spacer 160 improves the gap-filling capacity of the metal layer 170, the trench 140 is filled with the metal layer 170. In some embodiments, the metal layer 170 may be made of tungsten (W).

Referring to FIG. 6C, the first nitride spacer 160 and the metal layer 170 are planarized to form the contact 180 of the memory device 100a. Specifically, a planarization process is performed on the first nitride spacer 160 and the metal layer 170 to expose the top surface of the dielectric structure 120. After the planarization process, the top surfaces of the dielectric structure 120, the first nitride spacer 160, and the metal layer 170 may be substantially level with each other. The remained portions of the first nitride spacer 160 and the metal layer 170 form the contact 180 electrically connected to the gate structure 110, such that the contact 180 serves as the gate contact of the memory device 100a. In some embodiments, the contact 180 may be in direct contact with the gate structure 110, especially the gate electrode 112.

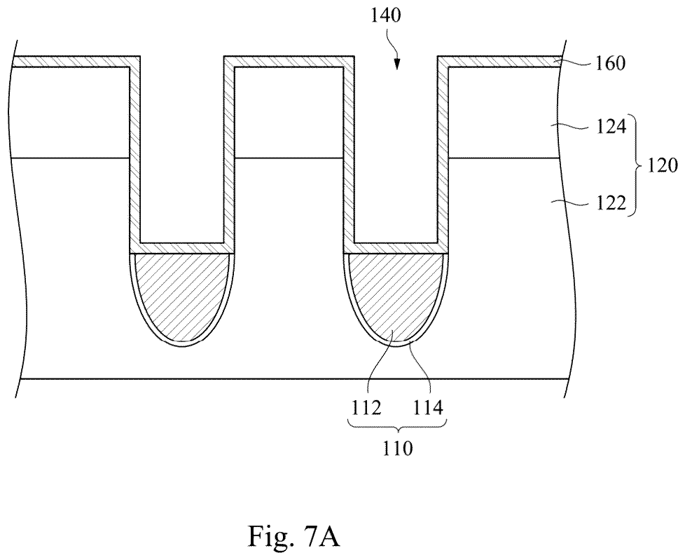

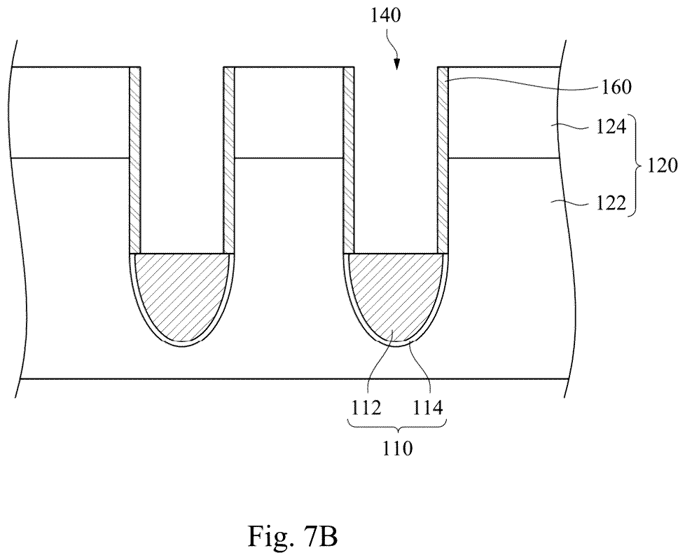

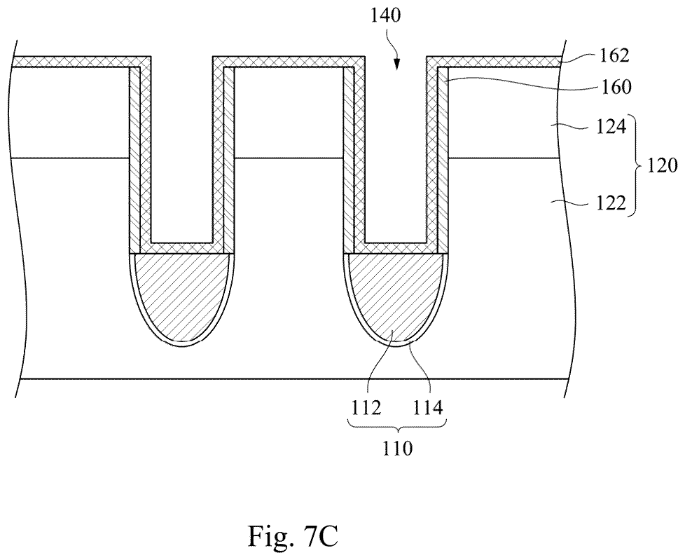

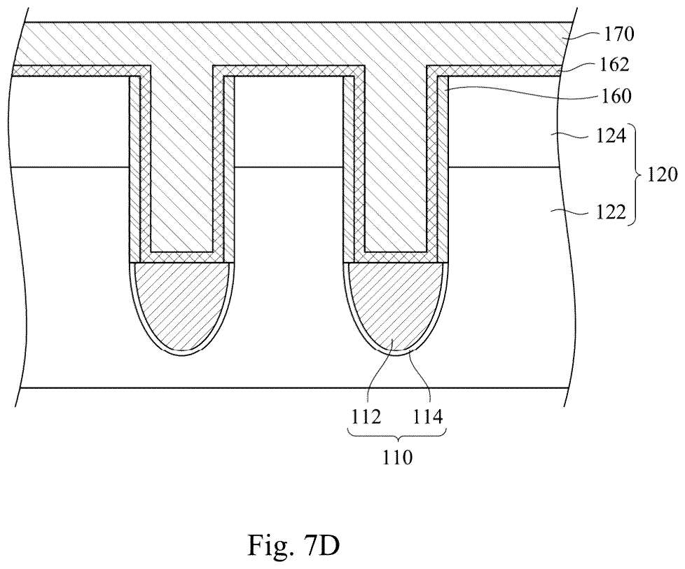

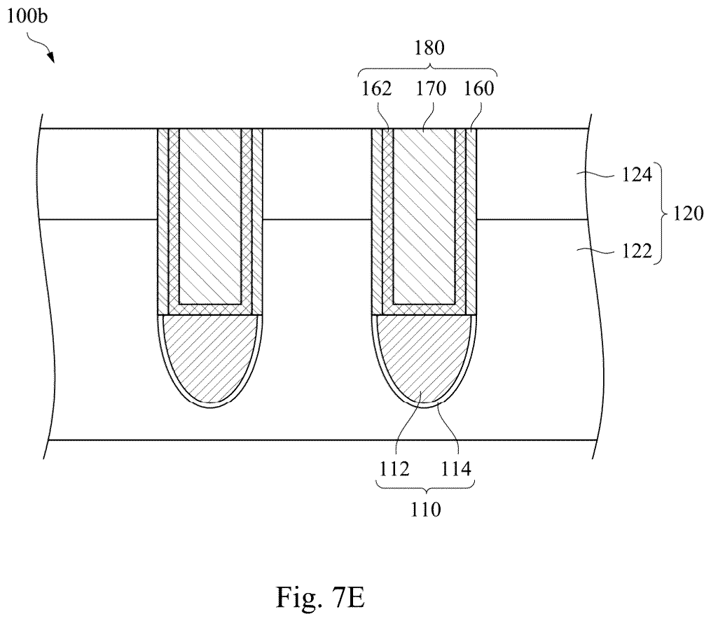

FIGS. 7A-7E illustrate cross-sectional views of another embodiment of the operation S150 of the method S100 in FIG. 1. Referring to FIG. 7A, a first nitride spacer 160 is formed to line the trench 140 and cover the gate electrode 112. Specifically, the first nitride spacer 160 may be conformally formed on the sidewalls of the trench 140, the bottom surface of the trench 140, and the top surface of the dielectric structure 120. After forming the first nitride spacer 160, a portion of the trench 140 is remained above the first nitride spacer 160, and the first nitride spacer 160 directly contacts the top surface of the gate electrode 112.

Referring to FIG. 7B, the first nitride spacer 160 is etched to expose the gate electrode 112. Specifically, an etching process, such as dry etching process, is performed to remove horizontal portions of the first nitride spacer 160 to expose the top surface of the gate electrode 112. The vertical portions of the first nitride spacer 160 may remain on sidewalls of the trench 140 once the etching process is completed. In some embodiments, the first nitride spacer 160 on the top surface of the dielectric structure 120 may also be removed once the etching process is completed.

Referring to FIG. 7C, a second nitride spacer 162 is formed to line the first nitride spacer 160 and cover the gate electrode 112. Specifically, the second nitride spacer 162 may be conformally formed on the sidewalls of the first nitride spacer 160, the top surface of the first nitride spacer 160, the top surface of the gate electrode 112, and the top surface of the dielectric structure 120 by, for example, chemical vapor deposition or atomic layer deposition. After forming the second nitride spacer 162, a portion of the trench 140 is remained above the second nitride spacer 162, and the second nitride spacer 162 directly contacts the top surface of the gate electrode 112.

In some embodiments, the second nitride spacer 162 and the gate electrode 112 may include a same metal nitride material, while the metal nitride material of the second nitride spacer 162 may be different from the nitride material of the first nitride spacer 160. For example, the first nitride spacer 160 may be made of a dielectric nitride material, such as SiN, while the second nitride spacer 162 is made of a conductive metal nitride material, such as TiN.

Referring to FIG. 7D, a metal layer 170 is formed to fill the trench 140. Specifically, the metal layer 170 is formed in the trench 140 and above the dielectric structure 120 by using deposition process, plating process, or other suitable techniques. The metal layer 170 directly contacts the second nitride spacer 162 while being separated from the gate structure 110, the first nitride spacer 160, and the dielectric structure 120. As the first nitride spacer 160 and the second nitride spacer 162 improves the gap-filling capacity and the adhesion for forming the metal layer 170, the trench 140 is filled with the metal layer 170.

Referring to FIG. 7E, the second nitride spacer 162 and the metal layer 170 are planarized to form the contact 180 of the memory device 100b. Specifically, a planarization process is performed on the second nitride spacer 162 and the metal layer 170 to expose the top surface of the dielectric structure 120. After the planarization process, the top surfaces of the dielectric structure 120, the first nitride spacer 160, the second nitride spacer 162, and the metal layer 170 may be substantially level with each other. The remained portions of the first nitride spacer 160, the second nitride spacer 162, and the metal layer 170 form the contact 180 electrically connected to the gate structure 110, such that the contact 180 serves as the gate contact of the memory device 100b. In some embodiments, the contact 180 may be in direct contact with the gate structure 110, especially the gate electrode 112.

In the following descriptions, a variety of measurements and evaluations were performed for the memory device of the present disclosure to specifically describe the advantageous of the present disclosure. First, the memory device of each Comparative example and Examples was formed according to the method S100 in FIG. 1 and operations in FIGS. 2-5 and 7A-7E. The gate electrode of each memory device is substantially composed of TiN. The component of the ashing gas of each Comparative example and Examples is shown in Table 1. Other materials and parameters remain the same between Comparative example and Examples, as described in the aforementioned contents.

Then, the contact resistance between the gate electrode and the contact of the memory device of each Comparative example and Examples was measured by the wafer acceptance test (WAT) using a four-point probe. The oxide distribution between the gate electrode and the contact was measured by Energy Dispersive X-Ray (EDX) Spectroscopy. The higher EDX oxide signal represents higher amount of oxide appears between the gate electrode and the contact. The result of each Comparative example and Examples is shown in Table 1.

TABLE 1

| | | Contact | EDX oxide |
|---|---|---|---|
| | Ashing gas | resistance (Ω) | signal |
| Comparative | 90% O₂ + 10% N₂H₂ | 900 | High |
| example | | | |
| Example 1 | 40% NH₃ + 60% O₂ | 91.61 | Low |
| Example 2 | 50% H₂ + 50% N₂ | 65.47 | Low |
| Example 3 | 4% H₂ + 96% N₂ | 74.37 | Low |

As seen from Table 1, the contact resistances of the Examples are all lower than the contact resistance of the Comparative example. In addition, the EDX oxide signals of the Examples are all lower than the EDX oxide signal. These results indicate that the components of the ashing gases of the Examples reduce the oxide formed between the gate electrode and the contact, which reduces the contact resistance between the gate electrode and the contact.

According to the above embodiments, the forming method of the memory device of the present disclosure includes removing the photoresist by an ashing gas that reaches the gate structure during the removing process. Since the ashing gas has an oxidizing capacity to oxidize a surface of a Si wafer into an oxide layer with a thickness thinner than 8 Å, the ashing gas may not oxidize the gate electrode of the gate structure, which reduces the possibility to form the oxide portion of the gate electrode. The ashing gas may also reduce the undesirably formed oxide portion of the gate electrode. Therefore, the contact resistance between the gate structure and the contact may be reduced, which improves the performance of the memory device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a memory device, comprising:
forming a photoresist on a dielectric structure;
forming a trench through the photoresist into the dielectric structure to expose a gate electrode embedded in the dielectric structure;
removing the photoresist by an ashing gas, wherein the ashing gas has an oxidizing capacity to oxidize a surface of a Si wafer into an oxide layer with a thickness thinner than 8 Å;
forming a first nitride spacer lining the trench and covering the gate electrode; and
forming a metal layer filling the trench.

2. The method of claim 1, wherein the ashing gas comprises a first ratio of H₂ and a second ratio of N₂, the second ratio is higher than or equal to the first ratio.

3. The method of claim 1, wherein the ashing gas comprises 4% to 50% of H₂ and 50% to 96% of N₂.

4. The method of claim 1, wherein the ashing gas comprises a first ratio of NH₃ and a second ratio of O₂, the second ratio is lower than or equal to 60%.

5. The method of claim 1, wherein the ashing gas comprises 40% to 50% of NH₃ and 50% to 60% of O₂.

6. The method of claim 1, wherein the gate electrode is made of a metal nitride material, and wherein the oxidizing capacity of the ashing gas is lower than an oxidizing capacity to oxidize the metal nitride material.

7. The method of claim 1, wherein a top surface of the gate electrode is exposed after forming the trench, and wherein the first nitride spacer directly contacts the top surface of the gate electrode after forming the first nitride spacer.

8. The method of claim 1, further comprising:
etching the first nitride spacer to expose the gate electrode after forming the first nitride spacer; and
forming a second nitride spacer lining the first nitride spacer and covering the gate electrode before forming the metal layer.

9. The method of claim 8, wherein the dielectric structure comprises a first dielectric layer and a second dielectric layer disposed on the first dielectric layer, and the first dielectric layer and the second dielectric layer comprise different materials.

10. The method of claim 8, wherein the metal layer is separated from the first nitride spacer by the second nitride spacer.

11. The method of claim 8, wherein the second nitride spacer and the gate electrode comprise a same material.

12. A method of forming a memory device, comprising:
providing a gate structure embedded in a dielectric structure, wherein the gate structure comprises a gate electrode and a gate dielectric surrounding the gate electrode;
forming a photoresist on the dielectric structure;
etching a trench through the photoresist into the dielectric structure to expose a top surface of the gate electrode, wherein at least a portion of the top surface of the gate electrode is oxidized into an oxide portion;
removing the photoresist by an ashing gas, wherein the oxide portion of the gate electrode is reduced by the ashing gas; and
forming a contact in the trench and in contact with the gate structure.

13. The method of claim 12, wherein an oxygen ratio of the ashing gas is lower than or equal to 60%.

14. The method of claim 12, wherein the ashing gas is free of oxygen.

15. The method of claim 12, wherein a component of the ashing gas is different from that of an etching gas for etching the trench.

16. The method of claim 12, wherein the top surface of the gate electrode is free of the oxide portion after removing the photoresist, such that the contact directly contacts the top surface of the gate electrode.

17. The method of claim 12, wherein the top surface of the gate electrode is fully exposed by the trench after etching the trench.

18. The method of claim 12, wherein a critical dimension of the gate structure is smaller than or equal to 18 nm.

19. The method of claim 12, wherein the gate electrode is substantially composed of TiN.

20. The method of claim 12, wherein the gate structure serves as a buried word line.
